(19) United States
(12) Patent Application Publication
(10) Pub. No.: US 2008/0237707 A1
(43) Pub. Date: Oct. 2, 2008

(54) SEMICONDUCTOR DEVICE

(75) Inventors: Fumito SUZUKI, Tokyo (JP); Koichi Endo, Tokyo (JP)

Correspondence Address: OBLON, SPIVAK, MCCLELLAND MAIER & NEUSTADT, P.C., 1940 DUKE STREET, ALEXANDRIA, VA, 22314, US

(73) Assignee: KABUSHIKI KAISHA TOSHIBA, Minato-Ku (JP)

(21) Appl. No.: 11/948,341

(22) Filed: Nov. 30, 2007

(30) Foreign Application Priority Data
Nov. 30, 2006 (JP) 2006-323001

(51) Int. Cl. H01L 29/78

(52) U.S. Cl. 257/344; 257/E29.268; 257/E29.007

(57) ABSTRACT

A semiconductor device includes a first semiconductor layer of a first conductivity type, a second semiconductor layer of the first conductivity type provided on the first semiconductor layer, having a lower impurity concentration than the first semiconductor layer, a third semiconductor layer of a second conductivity type provided on the second semiconductor layer, a base region of the second conductivity type provided in the third semiconductor layer, a source region of the first conductivity type provided in the base region, a first drain region of the first conductivity type provided in the third semiconductor layer, the first drain region being apart from the base region, a lightly doped drain region of the first conductivity type provided between the first drain region and the source region, the lightly doped drain region being in contact with the first drain region, the lightly doped drain having lower impurity concentration than the first drain region, a second drain region of the first conductivity type provided in the third semiconductor layer, and provided between the second semiconductor layer and the first drain region, the second drain region being in contact with the first drain region, a third drain region of the second conductivity type provided in the third semiconductor layer, provided between the second drain region and the second semiconductor layer, the third drain region being in contact with the second drain region.

### CROSS REFERENCE TO RELATED APPLICATION

This application is based upon and claims the benefit of priority from Japanese Patent Application No. 2006-323001, filed on Nov. 30, 2006, the entire contents of which are incorporated herein by reference.

### BACKGROUND

A power device, such as power IC having a high break down voltage MOS FET, is widely applied for high voltage large current use.

In a MOSFET, a leak current between the source and drain may be increased with the size of MOSFET become smaller. The leak current may occur especially in a power device, since a high electric field is provided between the source and drain.

### SUMMARY

Aspects of the invention relate to an improved semiconductor device.

In one aspect of the present invention, a semiconductor device may include a first semiconductor layer of a first conductivity type, a second semiconductor layer of the first conductivity type provided on the first semiconductor layer, having a lower impurity concentration than the first semiconductor layer, a third semiconductor layer of a second conductivity type provided on the second semiconductor layer, a base region of the second conductivity type provided in the third semiconductor layer, a source region of the first conductivity type provided in the base region, a first drain region of the first conductivity type provided in the third semiconductor layer, the first drain region being apart from the base region, a lightly doped drain region of the first conductivity type provided between the first drain region and the source region, the lightly doped drain region being in contact with the first drain region, the lightly doped drain having lower impurity concentration than the first drain region, a second drain region of the first conductivity type provided in the third semiconductor layer, and provided between the second semiconductor layer and the first drain region, the second drain region being in contact with the first drain region, a third drain region of the second conductivity type provided in the third semiconductor layer, provided between the second drain region and the second semiconductor layer, the third drain region being in contact with the second drain region, a gate electrode provided on the third semiconductor layer and the base region via a gate dielectric, the gate electrode provided between the source region and the first drain region, a source electrode provided on the source region, and a drain electrode provided on the first drain electrode.

In another aspect of the present invention, a semiconductor device may include a first semiconductor layer of a second conductivity type, a second semiconductor layer of a first conductivity type provided on the first semiconductor layer, having a lower impurity concentration than the first semiconductor layer, a third semiconductor layer of a second conductivity type provided on the second semiconductor layer, a base region of the second conductivity type provided in the third semiconductor layer, a source region of the first conductivity type provided in the base region, a first drain region of the first conductivity type provided in the third semiconductor layer, the first drain region being apart from the base region, a lightly doped drain region of the first conductivity type provided between the first drain region and the source region, the lightly doped drain region being in contact with the first drain region, the lightly doped drain having lower impurity concentration than the first drain region, a second drain region of the first conductivity type provided in the third semiconductor layer, and provided between the second semiconductor layer and the first drain region, the second drain region being in contact with the first drain region, a third drain region of the second conductivity type provided in the third semiconductor layer, provided between the second drain region and the second semiconductor layer, the third drain region being in contact with the second drain region, a gate electrode provided on the third semiconductor layer and the base region via a gate dielectric, the gate electrode provided between the source region and the first drain region, a source electrode provided on the source region, and a drain electrode provided on the first drain electrode.

### BRIEF DESCRIPTIONS OF THE DRAWINGS

A more complete appreciation of the invention and many of the attendant advantages thereof will be readily obtained as the same becomes better understood by reference to the following detailed description when considered in connection with the accompanying drawings.

FIG. 1 is a cross sectional view of a semiconductor device in accordance with a first embodiment.

FIG. 2 is a cross sectional view of a semiconductor device in accordance with a first modification of the first embodiment.

FIG. 3 is a cross sectional view of a semiconductor device in accordance with a second modification of the first embodiment.

FIG. 4 is a cross sectional view of a semiconductor device in accordance with a second embodiment.

FIG. 5 is a cross sectional view of a semiconductor device in accordance with a first modification of the second embodiment.

FIG. 6 is a cross sectional view of a semiconductor device in accordance with a second modification of the second embodiment.

FIG. 7 is a cross sectional view of a semiconductor device in accordance with a comparative example.

FIG. 8 is a characteristic diagram showing a breakdown voltage of the semiconductor device shown in FIG. 7.

FIG. 9 is a cross sectional view of a semiconductor device in accordance with a first modification of the embodiments.

FIG. 10 is a cross sectional view of a semiconductor device in accordance with a second modification of the embodiments.

FIG. 11 is a cross sectional view of a semiconductor device in accordance with a third modification of the embodiments.

FIG. 12 is a cross sectional view of a semiconductor device in accordance with a fourth modification of the embodiments.

FIG. 13 is a cross sectional view of a semiconductor device in accordance with a fifth modification of the embodiments.

### DETAILED DESCRIPTION

Various connections between elements are hereinafter described. It is noted that these connections are illustrated in general and, unless specified otherwise, may be direct or indirect and that this specification is not intended to be limiting in this respect.

Embodiments of the present invention will be explained with reference to the drawings as next described, wherein like reference numerals designate identical or corresponding parts throughout the several views.

Embodiments of the present invention will be explained with reference to the drawings as follows.

### FIRST EMBODIMENT

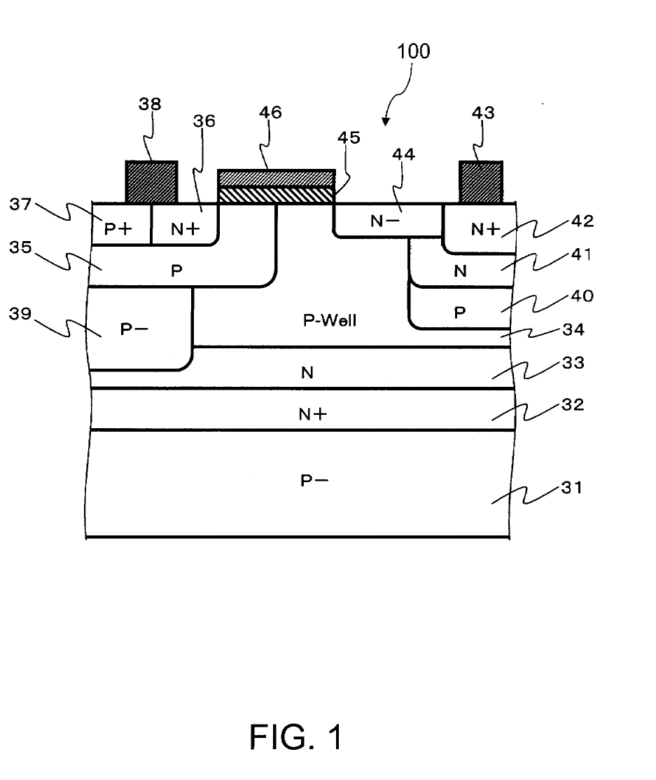

A first embodiment of the present invention will be explained hereinafter with reference to FIGS. 1-3.

FIG. 1 is a cross sectional view of a semiconductor device in accordance with a first embodiment. FIG. 1 shows a structure of an LDMOS (Lateral Double diffusion MOSFET) 100. The LDMOS 100 may be used for high breakdown voltage application.

As shown in FIG. 1, in the LDMOS 100, an N+ type semiconductor layer 32 as a first semiconductor layer is provided on a P− type semiconductor substrate 31. An N type semiconductor layer 33 as a second semiconductor layer is provided on the N+ type semiconductor layer 32. A P type well 34 as a third semiconductor layer 34 is provided on the N type semiconductor layer 33. The N+ type semiconductor layer 32 has a higher impurity concentration than the N type semiconductor layer 33. The N+ type semiconductor layer 32 may have P (Phosphorus) as the N type impurity. The P− type semiconductor substrate 31 and the P type well 34 may have B (boron) as the P type impurity.

A P type base region 35 is provided in the P type well 34. In the P type base region 35, a P+ type source region 37 and an N+ type drain region 36 is provided. On the P+ type source region 37 and the N+ type drain region 36, a source electrode 38 is provided. A bottom of the base region 35 is apart from the N+ type semiconductor layer 34 and is not in contact with the N+ type semiconductor layer 32. A P− type diffusion region 39 is provided in the P well 34 and the N type semiconductor layer 33. The P− type diffusion region 39 is provided between the base region 35 and the second semiconductor layer 33. The P− type diffusion region 39 is in contact with the base region 35. The diffusion region 39 is not in contact with the first semiconductor layer 32. The diffusion region 39 has a lower impurity than the base region 35. The base region 35 has a higher impurity than the P well 34. The P− type diffusion region 39 may be configured to reduce a base impurity concentration of a parasitic bipolar.

An N+ type first drain region 42 is provided in the P well 34. The N+ type first drain region 42 is provided in the surface of the P well 34. A drain electrode 43 is provided on the first drain region 42.

An N− type lightly doped drain (LDD) region 44 is provided in the P well 34. The N− type lightly doped drain region 44 is provided in the surface of the P well 34. The lightly doped drain region 44 is in contact with the N+ type first drain region 42 and extended toward the P+ type source region 37 and the N+ type source region 36.

An N type second drain region 41 is provided in the P well 34. The N type second drain region 41 is provided under the first drain region 42. The N type second drain region 41 is in contact with the first drain region 42 and the lightly doped drain region 44. However, the N type second drain region 41 may be not in contact with the lightly doped drain region 44. The second drain region 41 has a lower impurity concentration than the first drain region 42.

A P type third drain region 40 is provided in the P well 34. The third drain region is provided under the second semiconductor region 40. As in FIG. 1, the third drain region 40 is not in contact with the N type semiconductor layer 33. The third drain region 40 has a higher impurity concentration than the P well 34. The third drain region 40 is in contact with a bottom of the second drain region 41.

A gate dielectric 45 is provided on the surface of the base region and the P well 34 and between the source electrode 38 and the drain electrode 43. The gate dielectric 45 may be a gate oxide. A gate electrode 46 is provided on the gate dielectric 45.

In this first embodiment, the N type second drain region, which has a lower impurity concentration, is provided in contact with the N+ type first drain region 42, and the P type third drain region 40, which is of opposite conductivity, is provided under or below the second drain region 41.

So, when a voltage is applied between the source electrode 38 and the drain electrode 43, the depletion layer is provided between the second drain region 41 and the third drain region 40. A breakdown voltage may be increased by the depletion layer. A possibility of punch through of the carrier between the first drain region 52 and the second semiconductor layer 32 may be reduced.

An impurity concentration of the N type second semiconductor layer 33 may be no less than 1×10¹³ cm⁻². An impurity concentration of the P type well 34 may be no more than 1×10¹³ cm⁻². An impurity concentration of the N+ type first drain region 42 may be no less than 1×10¹⁴ cm².

An impurity concentration of the lightly doped drain region 44 may be from 1×10¹¹ cm⁻² to 1×10¹³ cm⁻². An impurity concentration of the second drain region 41 may be from 1×10¹² cm⁻² to 1×10¹⁴ cm⁻². An impurity concentration of the third drain region 40 may be from 1×10¹² cm⁻² to 1×10¹⁴ cm⁻².

The second drain region 41 has a lower impurity concentration than the first drain region 42. The second drain region 41 has a lower impurity concentration than the second semiconductor layer 34.

The third drain region 40 has a lower impurity concentration than the first drain region 42. The third drain region 40 has a lower impurity concentration than the second semiconductor layer 34.

The lightly doped drain region 44 has a lower impurity concentration than the first drain region 42.

Next, a manufacturing process of the LDMOS 100 will be explained hereinafter.

A p type ion, such as Sb (antimony), is implanted into the P− type semiconductor substrate 31, in which boron or the like is doped. The N type semiconductor layer 33 is formed on the N+ type semiconductor layer 32 by epitaxial growing.

A resist mask for lithography is formed on the N type semiconductor layer 33, and an ion is implanted in a region where the resist mask is not provided.

The P type semiconductor region (P well) 34 is formed on the N type semiconductor layer 33 by implanting B ion.

The P− type diffusion region 39 is formed on the N type semiconductor layer 33 by implanting B ion.

The third drain region 40 is formed in the P well 34 by implanting B ion. The second drain region 41 is formed in the P well 34 by implanting P (phosphorus) ion.

Next a field oxide (not shown in FIG. 1) is formed on the surface of the P well 34. Implanting ion for the third drain region 40 and the second drain region 41 may be operated after forming the field oxide.

The base region 35 is formed by implanting B ion in the P well 34. The gate dielectric 45 is formed on the base region 35 and the P well 34. The N+ source region 36 and the N+ type first drain region is formed by implanting P (phosphorus). The P+ type source region 37 is formed by implanting B ion. The lightly doped drain region 44 is formed between the gate and the drain region by implanting P (phosphorus) ion.

The drain electrode 43, the source electrode 38, and the gate electrode 46 are formed on the first drain region 40, the N+ drain region 36, P+ drain region and the gate dielectric, respectively.

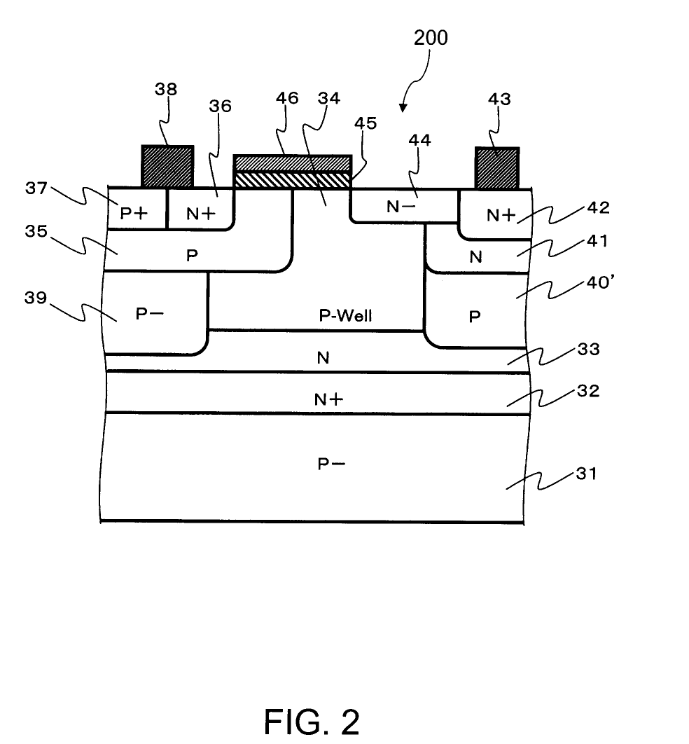

A first modification of the first embodiment will be explained hereinafter in accordance with FIG. 2. FIG. 2 is a cross sectional view of a semiconductor device in accordance with a first modification of the first embodiment.

As shown in FIG. 2, in a LDMOS 200, a third drain region 40′ is in contact with the second semiconductor layer 33 and not in contact with the first semiconductor layer 32. The third drain region 40′ is extended from the bottom of the second drain region 41 to the second drain region 33. In the LDMOS 200, the possibility of punch through occurring between the first semiconductor layer 32 and the first drain region 42 may be reduced. Punch through of carriers in the LDMOS 200 may be reduced more than that in the LDMOS 100 as shown in FIG. 1.

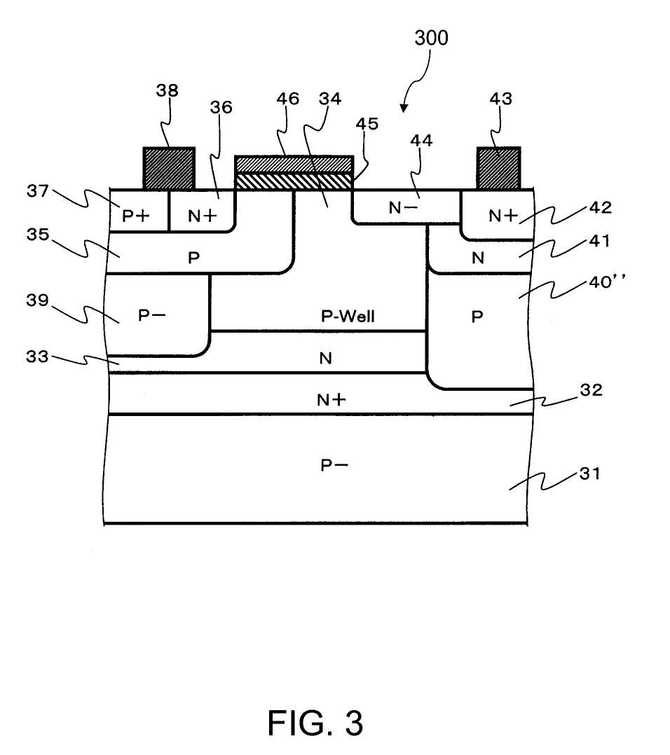

A second modification of the first embodiment will be explained hereinafter in accordance with FIG. 3. FIG. 3 is a cross sectional view of a semiconductor device in accordance with the second modification of the first embodiment.

As shown in FIG. 3, in a LDMOS 300, a third drain region 40″ is in contact with the first semiconductor layer 32. The third drain region 40″ is extended from the bottom of the second drain region 41 to the first semiconductor layer 32. In the LDMOS 200, the possibility of occurring punch through between the first semiconductor layer 32 and the first drain region 42 may be reduced. Punch through of carriers in the LDMOS 300 may be reduced more than that in the LDMOS 200 as shown in FIG. 2.

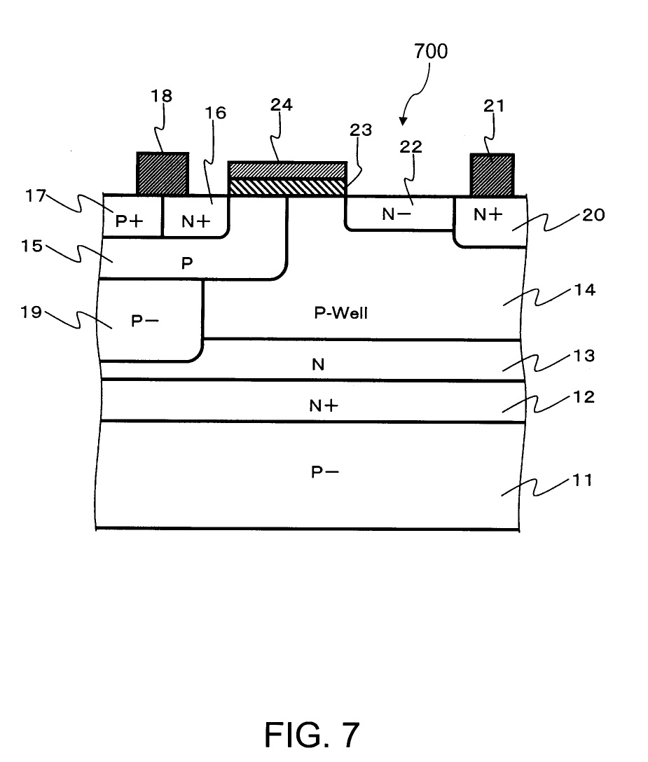

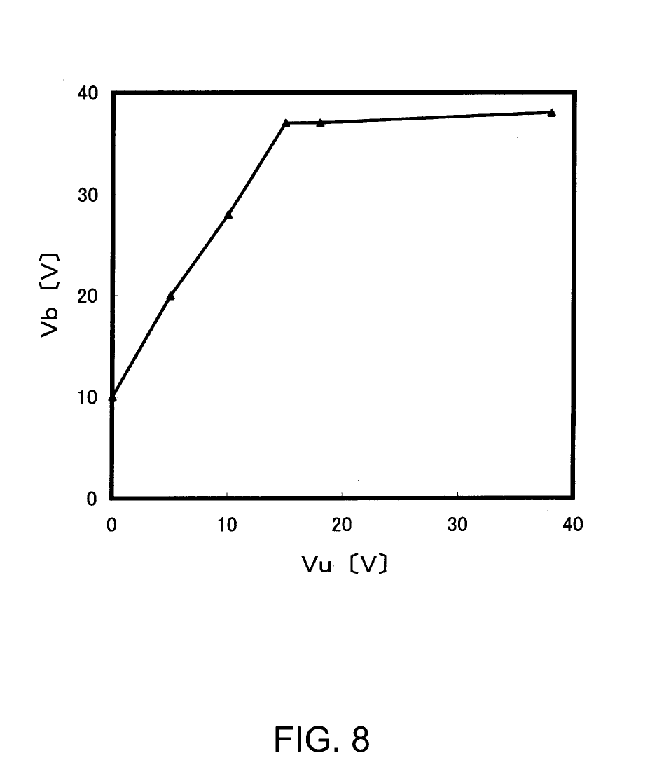

A comparative example will be explained herein after with reference to FIGS. 7 and 8.

In the comparative example, the second drain region and the third drain region are not provided in the LDMOS 700.

As shown in FIG. 7, in the LDMOS 700, an N+ type semiconductor layer 12 as is provided on a P− type semiconductor substrate 11. An N type semiconductor layer 13 is provided on the N+ type semiconductor layer 12. A P type well 14 is provided on the N type semiconductor layer 13.

AP type base region 15 is provided in the P type well 14. In the P type base region 15, a P+ type source region 17 and an N+ type drain region 16 is provided. On the P+ type source region 17 and the N+ type drain region 16, a source electrode 18 is provided. A P− type diffusion region 19 is provided in the P well 14 and the N type semiconductor layer 13. The P− type diffusion region 19 is provided between the base region 15 and the second semiconductor layer 13. The P− type diffusion region 19 is in contact with the base region 15. The diffusion region 19 is not in contact with the first semiconductor layer 12. The diffusion region 19 has a lower impurity than the base region 15. The base region 15 has a higher impurity than the P well 14.

An N+ type first drain region 20 is provided in the P well 14. The N+ type first drain region 20 is provided in the surface of the P well 14. A drain electrode 21 is provided on the first drain region 20.

An N− type lightly doped drain (LDD) region 22 is provided in the P well 14. The N− type LDD region 22 is provided in the surface of the P well 14. The LDD region 22 is in contact with the N+ type first drain region 20 and extended toward the P+ type source region 17 and the N+ type source region 16.

A gate dielectric 23 is provided on the surface of the base region and the P well 14 and between the source electrode 18 and the drain electrode 21. A gate electrode 24 is provided on the gate dielectric 23.

A relationship between a voltage Vu of the N+ type semiconductor layer 12 and a drain voltage Vb, when the source electrode 18 and the gate electrode 24 is short-circuited and connected to GND, is shown in FIG. 8.

When Vu is 0 V, the breakdown occurs with the drain voltage Vb is about 10 V. In order to avoid breakdown when the drain voltage Vb is no less than 35 V, it is necessary that the voltage Vu is no less than 15 V. In case the voltage Vu is high voltage, the impurity concentration of the N+ type semiconductor layer 20 is set a high value. So, a capacitance may be increased and frequency characteristics may be worsened in the Si substrate 11 or N+ semiconductor layer 12, and it may be difficult to switch at high speed. The breakdown may occur between the drain electrode 21 and N+ type semiconductor layer 20.

### SECOND EMBODIMENT

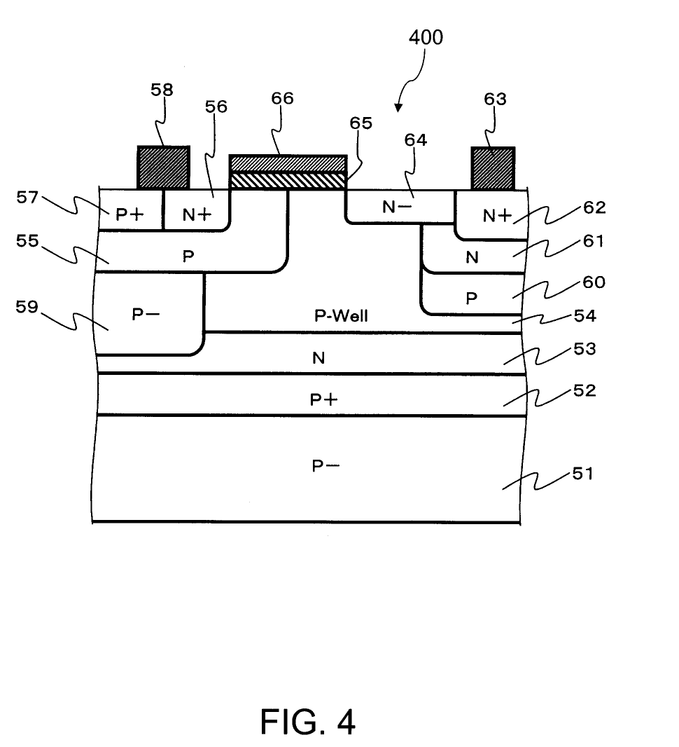

A second embodiment is explained with reference to FIGS. 4-6.

A semiconductor device is described in accordance with a second embodiment of the present invention. With respect to each portion of this embodiment, the same or corresponding portions of the semiconductor device of the first embodiment shown in FIGS. 1-3 are designated by the same reference numerals, and explanation of such portions is omitted.

As shown in FIG. 4, a P+ type semiconductor layer 52 is provided. In the LDMOS 400, a P+ type semiconductor layer 52 as a first semiconductor layer is provided on a P− type semiconductor substrate 51. An N type semiconductor layer 53 as a second semiconductor layer is provided on the P+ type semiconductor layer 52. A P type well 54 as a third semiconductor layer is provided on the N type semiconductor layer 53. The P+ type semiconductor layer 52 has a higher impurity concentration than the N type semiconductor layer 53. The P+ type semiconductor layer 52 may have B (Boron) as the P type impurity. The P− type semiconductor substrate 51 may have B (boron) as the P type impurity. The P type well 54 may have B (boron) as the P type impurity.

A P type base region 55 is provided in the P type well 54. In the P type base region 55, a P+ type source region 57 and an N+ type drain region 56 is provided. On the P+ type source region 57 and the N+ type drain region 56, a source electrode 58 is provided. A bottom of the base region 55 is apart from the P+ type semiconductor layer 52 and is not in contact with the P+ type semiconductor layer 52. A P− type diffusion region 59 is provided in the P well 54 and the N type semiconductor layer 53. The P− type diffusion region 59 is provided between the base region 55 and the second semiconductor layer 53, is in contact with the base region 55 and is not in contact with the first semiconductor layer 52. The diffusion region 59 has a lower impurity than the base region 55. The base region 55 has a higher impurity than the P well 54.

An N+ type first drain region 62 is provided in the P well 54. The N+ type first drain region 62 is provided in the surface of the P well 54. A drain electrode 63 is provided on the first drain region 62.

An N− type LDD region 64 is provided in the P well 54. The N− type LDD region 64 is provided in the surface of the P well 54. The LDD region 64 is in contact with the N+ type first drain region 62 and extended toward the P+ type source region 57 and the N+ type source region 56.

An N type second drain region 61 is provided in the P well 54. The N type second drain region 61 is provided under the first drain region 62. The N type second drain region 61 is in contact with the first drain region 62 and the lightly doped drain region 64. However, the N type second drain region 61 may be not in contact with the lightly doped drain region 64. The second drain region 61 has a lower impurity concentration than the first drain region 62.

A P type third drain region 60 is provided in the P well 54. The third drain region is provided under the second drain region 61. As in FIG. 1, the third drain region 60 is not in contact with the N type semiconductor layer 53. The third drain region 60 has a higher impurity concentration than the P well 34. The third drain region 60 is in contact with a bottom of the second drain region 61.

A gate dielectric 65 is provided on the surface of the base region and the P well 54 and between the source electrode 58 and the drain electrode 63. The gate dielectric 65 may be a gate oxide. A gate electrode 66 is provided on the gate dielectric 65.

In this second embodiment, the N type second drain region 61, which has a lower impurity concentration, is provided in contact with the N+ type first drain region 62, and the P type third drain region 60, which is of opposite conductivity, is provided under or below the second drain region 61.

So, when a voltage is applied between the source electrode 58 and the drain electrode 63, the depletion layer is provided between the second drain region 61 and the third drain region 60. A breakdown voltage may be increased by the depletion layer. A possibility of punch through of the carriers between the first drain region 62 and the second semiconductor layer 52 may be reduced.

An impurity concentration of the N type second semiconductor layer 53 may be no less than 1×10¹³ cm⁻². An impurity concentration of the P type well 54 may be no more than 1×10¹³ cm⁻². An impurity concentration of the N+ type first drain region 62 may be no less than 1×10¹⁴ cm⁻².

An impurity concentration of the LDD region 64 may be from 1×10¹¹ cm⁻² to 1×10¹³ cm². An impurity concentration of the second drain region 61 may be from 1×10¹² cm⁻² to 1×10¹⁴ cm⁻². An impurity concentration of the third drain region 60 may be from 1×10¹² cm⁻² to 1×10¹⁴ cm⁻².

The second drain region 61 has a lower impurity concentration than the first drain region 62. The second drain region 61 has a lower impurity concentration than the second semiconductor layer 53.

The third drain region 60 has a lower impurity concentration than the first drain region 62. The third drain region 60 has a lower impurity concentration than the second semiconductor layer 53.

The LDD region 64 has a lower impurity concentration than the first drain region 62.

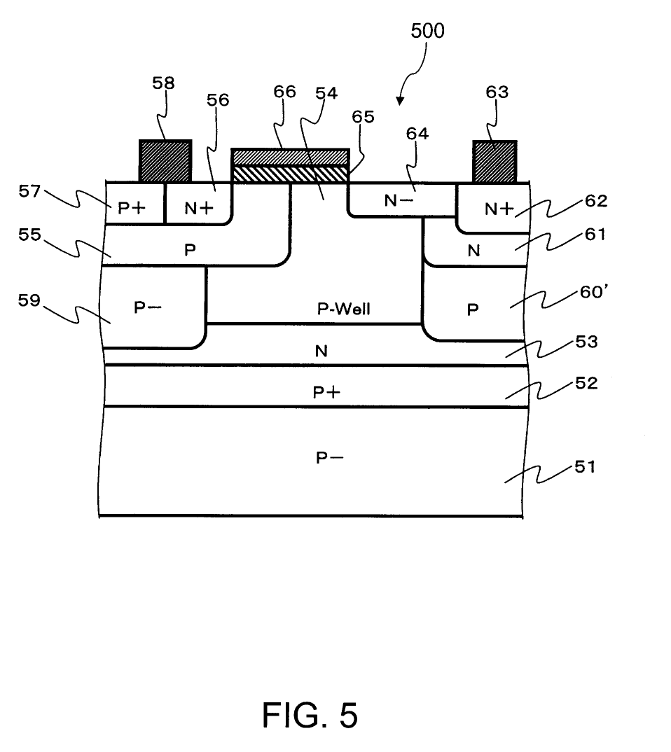

A first modification of the second embodiment will be explained hereinafter in accordance with FIG. 5. FIG. 5 is a cross sectional view of a semiconductor device in accordance with a first modification of the second embodiment.

As shown in FIG. 5, in a LDMOS 500, a third drain region 60′ is in contact with the second semiconductor layer 53 and not in contact with the first semiconductor layer 52. The third drain region 60′ extends from the bottom of the second drain region 61 to the second semiconductor layer 53. In the LDMOS 500, the possibility of punch through occurring between the first semiconductor layer 52 and the first drain region 62 may be reduced. Punch through of carriers in the LDMOS 500 may be reduced more than that in the LDMOS 400 as shown in FIG. 4.

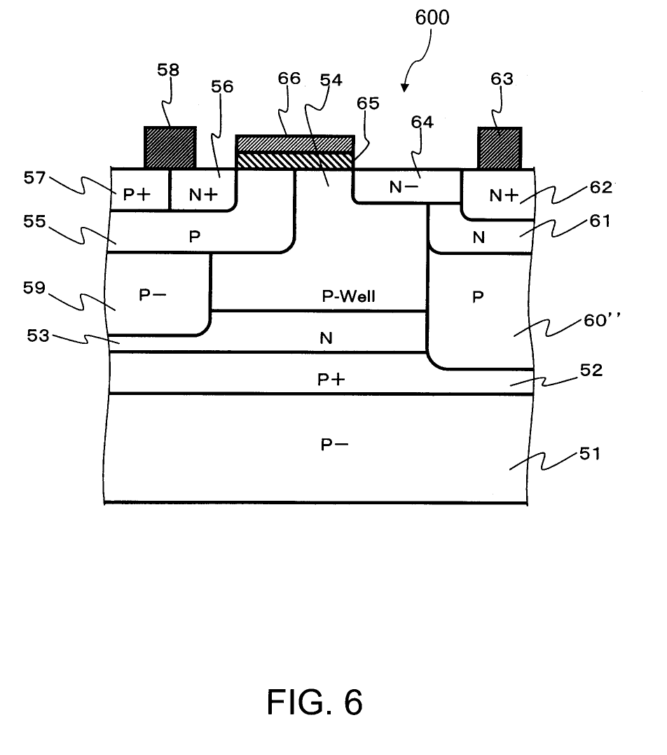

A second modification of the second embodiment will be explained hereinafter in accordance with FIG. 6. FIG. 6 is a cross sectional view of a semiconductor device in accordance with the second modification of the second embodiment.

As shown in FIG. 6, in a LDMOS 600, a third drain region 60″ is in contact with the first semiconductor layer 52. The third drain region 60″ extends from the bottom of the second drain region 61 to the first semiconductor layer 52. In the LDMOS 600, the possibility of punch through occurring between the first semiconductor layer 52 and the first drain region 62 may be reduced. Punch through of carriers in the LDMOS 600 may be reduced more than that in the LDMOS 400 as shown in FIG. 3.

Embodiments of the invention have been described with reference to the examples. However, the invention is not limited thereto.

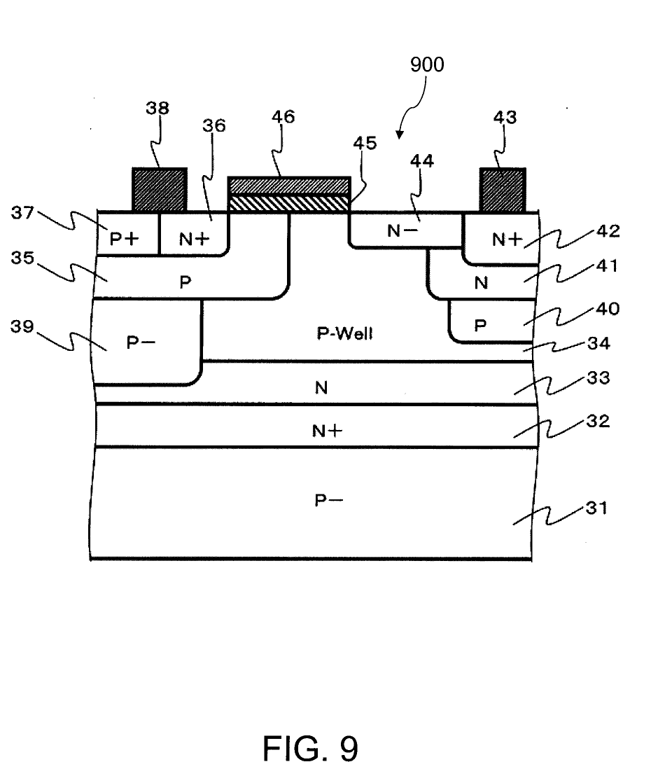

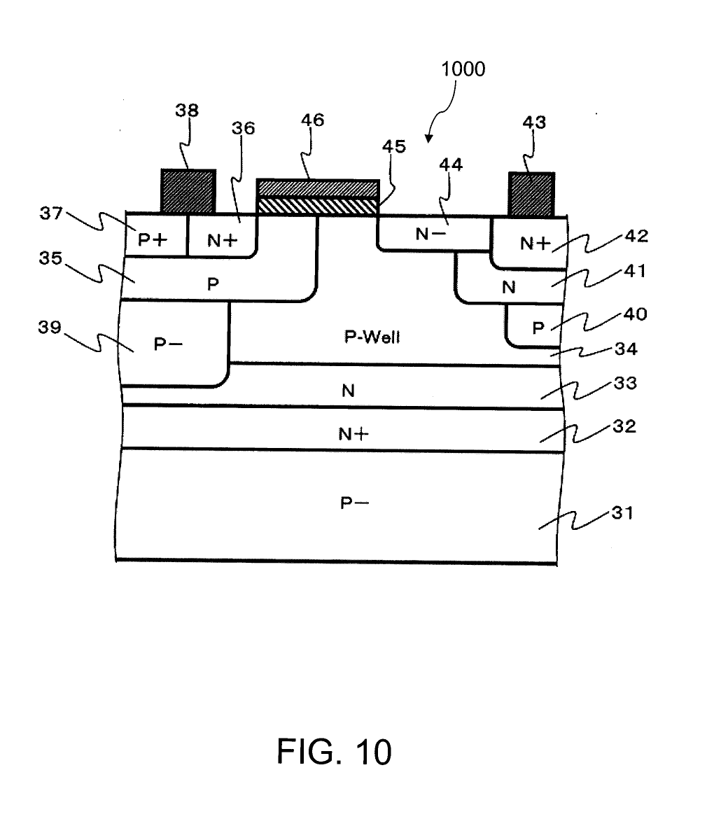

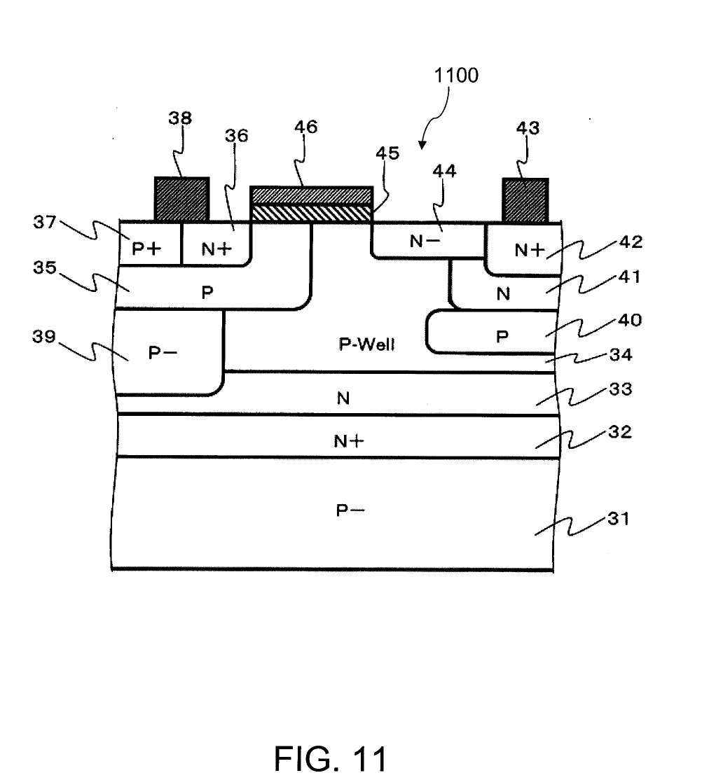

FIGS. 9-13 are cross sectional views of a semiconductor device in accordance with a modification of the embodiments.

As shown in FIGS. 9-13, a gate side edge (left side in FIGS. 9-13) of the third drain region 40 may not be aligned with a gate side edge (left side in FIGS. 9-13) of the second drain region 41.

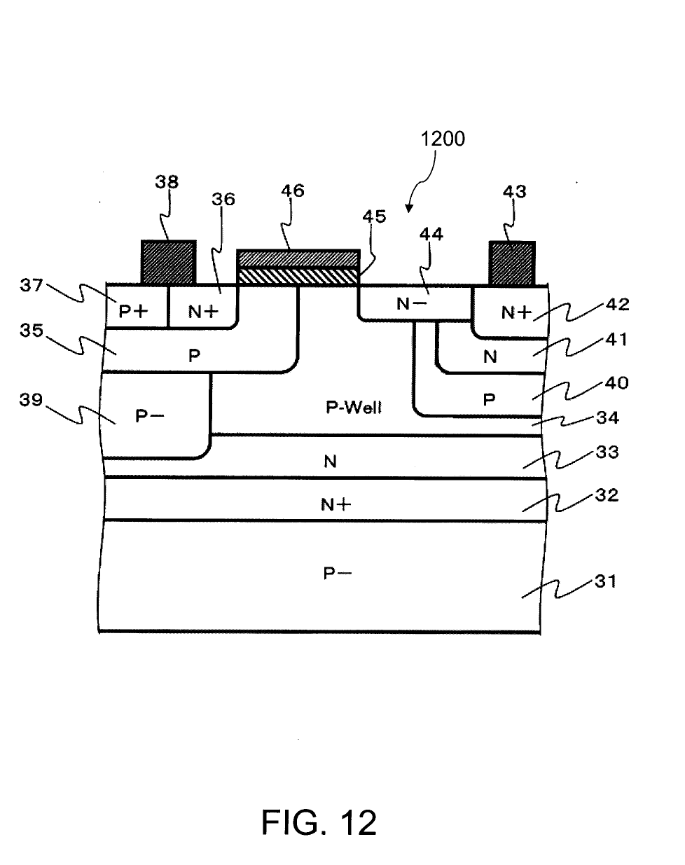

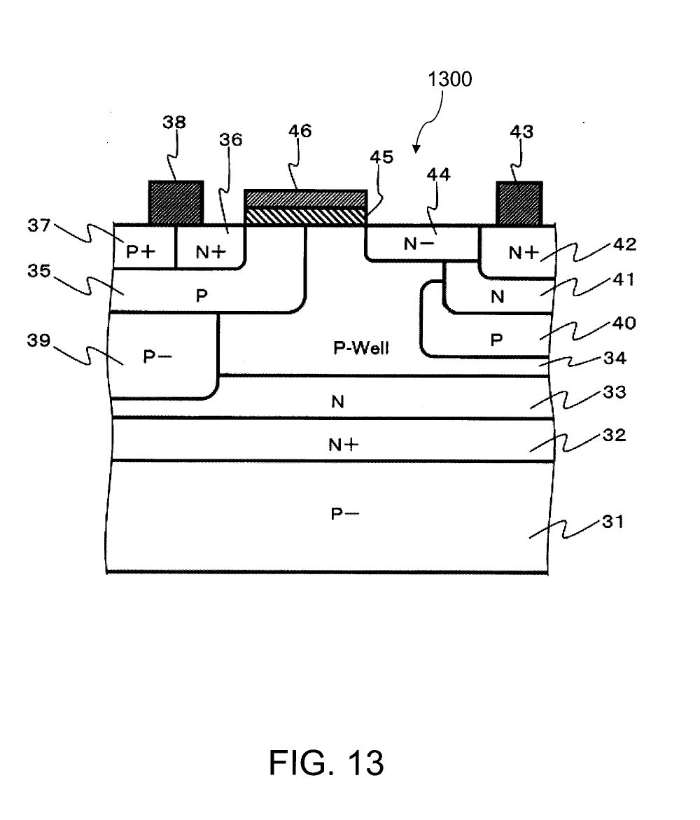

As shown in FIGS. 12 and 13, the third drain region 40 may be provided on the gate side (left side in FIGS. 12 and 13) of the second drain region 41.

The diffusion region 39 may be in contact with the N+ type semiconductor layer 32.

Other embodiments of the present invention will be apparent to those skilled in the art from consideration of the specification and practice of the invention disclosed herein. It is intended that the specification and example embodiments be considered as exemplary only, with a true scope and spirit of the invention being indicated by the following.

What is claimed is:

1. A semiconductor device, comprising:
a first semiconductor layer of a first conductivity type;
a second semiconductor layer of the first conductivity type provided on the first semiconductor layer, having a lower impurity concentration than the first semiconductor layer;
a third semiconductor layer of a second conductivity type provided on the second semiconductor layer;
a base region of the second conductivity type provided in the third semiconductor layer;
a source region of the first conductivity type provided in the base region;
a first drain region of the first conductivity type provided in the third semiconductor layer, the first drain region being apart from the base region;
a lightly doped drain region of the first conductivity type provided between the first drain region and the source region, the lightly doped drain region being in contact with the first drain region, the lightly doped drain region having a lower impurity concentration than the first drain region;
a second drain region of the first conductivity type provided in the third semiconductor layer, and provided between the second semiconductor layer and the first drain region, the second drain region being in contact with the first drain region;
a third drain region of the second conductivity type provided in the third semiconductor layer, provided between the second drain region and the second semiconductor layer, the third drain region being in contact with the second drain region, the third drain region having a higher impurity concentration than the third semiconductor layer;
a gate electrode provided on the third semiconductor layer and the base region via a gate dielectric, the gate electrode provided between the source region and the first drain region;
a source electrode provided on the source region; and
a drain electrode provided on the first drain electrode.

2. A semiconductor device of claim 1, wherein the second drain region has a lower impurity concentration than the first drain region.

3. A semiconductor device of claim 1, wherein the second drain region has a lower impurity concentration than the first drain region and a higher impurity concentration than the lightly doped drain region.

4. A semiconductor device of claim 2, wherein the second drain region has a higher impurity concentration than the third semiconductor layer.

5. A semiconductor device of claim 1, wherein the third drain region has a lower impurity concentration than the first drain region.

6. A semiconductor device of claim 5, wherein the third drain region is in contact with the second semiconductor region.

7. A semiconductor device of claim 6, wherein the second drain region has a lower impurity concentration than the first drain region.

8. A semiconductor device of claim 6, wherein the second drain region has a lower impurity concentration than the first drain region and a higher impurity concentration than the lightly doped drain region.

9. A semiconductor device of claim 6, wherein the third drain region has a lower impurity concentration than the first drain region.

10. A semiconductor device of claim 1, wherein the third drain region is in contact with the first semiconductor region.

11. A semiconductor device, comprising:
a first semiconductor layer of a second conductivity type;
a second semiconductor layer of a first conductivity type provided on the first semiconductor layer, having a lower impurity concentration than the first semiconductor layer;
a third semiconductor layer of a second conductivity type provided on the second semiconductor layer;
a base region of the second conductivity type provided in the third semiconductor layer;
a source region of the first conductivity type provided in the base region;
a first drain region of the first conductivity type provided in the third semiconductor layer, the first drain region being apart from the base region;
a lightly doped drain region of the first conductivity type provided between the first drain region and the source region, the lightly doped drain region being in contact with the first drain region, the lightly doped drain region having a lower impurity concentration than the first drain region;
a second drain region of the first conductivity type provided in the third semiconductor layer, and provided between the second semiconductor layer and the first drain region, the second drain region being in contact with the first drain region;
a third drain region of the second conductivity type provided in the third semiconductor layer, provided between the second drain region and the second semiconductor layer, the third drain region being in contact with the second drain region, and the third drain region having a higher impurity concentration than the third semiconductor layer;
a gate electrode provided on the third semiconductor layer and the base region via a gate dielectric, the gate electrode provided between the source region and the first drain region;
a source electrode provided on the source region; and
a drain electrode provided on the first drain electrode.

12. A semiconductor device of claim 11, wherein the second drain region has a lower impurity concentration than the first drain region.

13. A semiconductor device of claim 11, wherein the second drain region has a lower impurity concentration than the first drain region and a higher impurity concentration than the lightly doped drain region.

14. A semiconductor device of claim 12, wherein the second drain region has a higher impurity concentration than the third semiconductor layer.

15. A semiconductor device of claim 11, wherein the third drain region has a lower impurity concentration than the first drain region.

16. A semiconductor device of claim 15, wherein the third drain region is in contact with the second semiconductor region.

17. A semiconductor device of claim 15, wherein the second drain region has a lower impurity concentration than the first drain region.

18. A semiconductor device of claim 15, wherein the second drain region has a lower impurity concentration than the first drain region and a higher impurity concentration than the lightly doped drain region.

19. A semiconductor device of claim 15, wherein the third drain region has a lower impurity concentration than the first drain region.

20. A semiconductor device of claim 11, wherein the third drain region is in contact with the first semiconductor region.
